(19) United States
(12) Patent Application Publication
(10) Pub. No.: US 2009/0008757 A1
(43) Pub. Date: Jan. 8, 2009

(54) METHOD OF FABRICATING SUBSTRATE FOR PACKAGE OF SEMICONDUCTOR LIGHT-EMITTING DEVICE

(76) Inventor: Wan-Shun CHOU, Taipei County (TW)

Correspondence Address: Muncy, Geissler, Olds & Lowe, PLLC, P.O. BOX 1364, FAIRFAX, VA, 22038-1364, US

(21) Appl. No.: 12/208,858

(22) Filed: Sep. 11, 2008

Related U.S. Application Data
(63) Continuation of application No. 11/287,404, filed on Nov. 28, 2005.

(30) Foreign Application Priority Data
Jul. 1, 2005 (TW) 094211176

(51) Int. Cl. H01L 23/495

(52) U.S. Cl. 257/676; 257/E23.031

(57) ABSTRACT

In the invention, a substrate and fabrication thereof for a package of at least one semiconductor device, such as semiconductor light-emitting devices, are disclosed. In particular, a base together with a frame supporting the base of the substrate according to the invention is formed of a thick-walled metal material, a special-shaped metal plate or a normal-shaped metal plate. The at least one semiconductor device is to mounted on a top surface of the base. Moreover, the base serves as a heat sink.

### CROSS REFERENCE TO RELATED APPLICATIONS

This application is a Continuation of co-pending application Ser. No. 11/287,404 filed on Nov. 28, 2005, and for which priority is claimed under 35 U.S.C. § 120; and this application claims priority of Application No. 094211176 filed in Taiwan R.O.C. on Jul. 1, 2005 under 35 U.S.C. § 119; the entire contents of all of which are hereby incorporated by reference.

### BACKGROUND OF THE INVENTION

1. Field of the Invention

The invention relates to a method of fabricating substrate, and more particularly, to a method of fabricating substrate for package of semiconductor device.

2. Description of the Prior Art

Semiconductor chip, e.g. semiconductor light-emitting devices, has been utilized everywhere in our daily life. The advantages of using these semiconductor products, such as small volume and power-saving, facilitate the development of them. However, many of these semiconductor products have the same problem of the rise of temperature which can lead to low efficiency of the operation of the semiconductor chip, even short life-span of the semiconductor chip. A semiconductor chip mounting part, which has excellent heat conduction and dissipation capabilities, is important for a substrate for a package of semiconductor chip.

Moreover, heat dissipating devices, e.g. a heat sink, nowadays often formed by metal materials with excellent heat conductivity, such as copper or aluminum materials, and then be mounted to the semiconductor chip or the carrier of the semiconductor chip. The mounting process of the heat dissipating device can lead to extra costs when manufacturing the substrate.

### SUMMARY OF THE INVENTION

Accordingly, the scope of the present invention is to provide a substrate for a package of at least one semiconductor device, which does not need the extra mounting process of the heat dissipating device, and a method of fabricating the substrate. More particularly, the method can reduce the complexity of the process of fabricating the substrate.

The preferred embodiment, according to the invention, provides a method of fabricating a substrate for a package of at least one semiconductor device. First of all, a first metal plate is punched to form a first frame, a base substantially formed at a center of the first frame, and at least one first supporting part which each is formed to connect between the first frame and the base. In addition, the base has a circumference, a bottom surface, and a top surface.

Afterward, a second metal plate is punched to form a second frame which can mate the first frame. N bonding part, which each has a respective bond pad, is formed apart from a center of the second frame. Furthermore, N outer electrodes, which each is utilized to connect between the second frame and one of the bonding parts, are formed. N is a positive integer larger than or equal to 2.

Then, the second frame is aligned with the first frame, and is palletized on the first frame. Accordingly, the bonding parts are disposed around the circumference of the base and spaced from the base.

Finally, an insulating material is molded to substantially pack the base and the bonding parts, so as to expose the top surface and the bottom surface of the base and the bond pads. When the at least one semiconductor device is mounted on the top surface of the base, the electrodes of the at least one semiconductor device are to be wired to the bond pads.

A substrate for a package of at least one semiconductor device according to the invention comprises a base, N bonding parts, N outer electrodes, and an insulating material. N is a positive integer larger than or equal to 2.

The base has a circumference, a bottom surface and a top surface which the at least one semiconductor device is to be mounted on. Furthermore, the N bonding parts, which each is disposed around the circumference of the base, are spaced from the base, and has a respective bond pad which at least one of the electrodes of the at least one semiconductor device is to be wired to. In addition, each of the N outer electrodes protrudes from one of the bonding parts. Moreover, an insulating material is molded to substantially pack the base and the bonding parts, so as to expose the top surface and the bottom surface of the base, and the bond pads.

After the package of the at least one semiconductor device is finished, a heat generated during operation of the at least one semiconductor device is conducted from the top surface to the bottom surface of the base, and then is dissipated at the bottom surface of the base.

The scope of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1A is a top view of a substrate for a package of at least one semiconductor device according to one embodiment of the invention.

FIG. 1B is a side view of the substrate for a package of at least one semiconductor device shown in FIG. 1A.

FIG. 1C is a bottom view of the substrate for a package of at least one semiconductor device shown in FIG. 1A.

FIG. 2 shows a top view of a substrate for a package of at least one semiconductor device according to one embodiment of the invention.

FIG. 3A through FIG. 3D illustrate a method of fabricating a substrate for a package of at least one semiconductor device according to one embodiment of the invention.

### DETAILED DESCRIPTION OF THE INVENTION

The present invention provides a method of fabricating substrate for package of semiconductor light-emitting device.

A substrate for a package of at least one semiconductor device, in accordance with the invention comprises a base, N bonding parts, N outer electrodes, and an insulating material. It should be noted that N is a positive integer larger than or equal to 2. In practice, the at least one semiconductor device is a semiconductor light-emitting device.

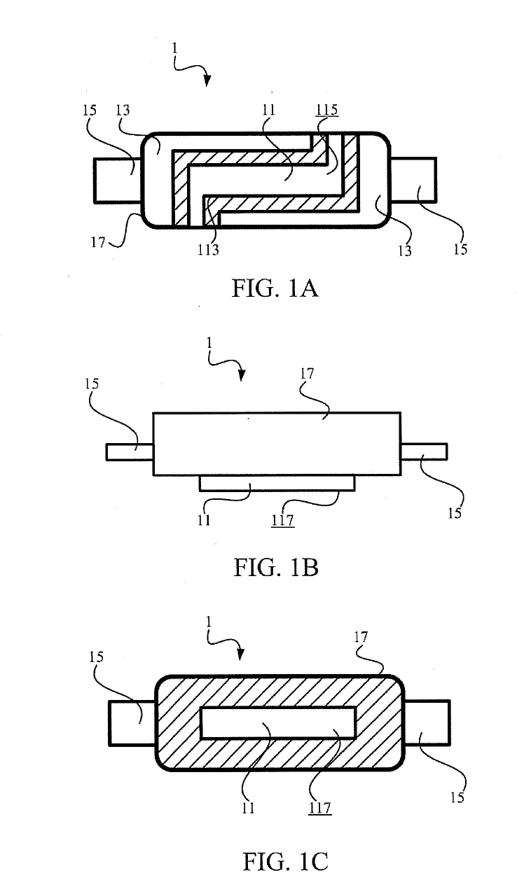

Please refer to FIG. 1A, FIG. 1B, and FIG. 1C which shows respectively a top view, a side view, and a bottom view of a substrate 1 for a package of at least one semiconductor device (not shown) according to one embodiment of the invention. In the embodiment, the substrate 1 comprises a base 11, two bonding parts 13, two outer electrodes 15, and an insulating material 17.

The base 11 has a circumference 113, a bottom surface 117 and a top surface 115. Moreover, the at least one semiconductor device is to be mounted on the top surface 115 of the base 11. In practice, the base 11 can be formed of a thick-walled metal material.

The bonding parts 13, which each has a respective bond pad (not shown), are disposed around the circumference 113 of the base 11, and spaced from the base 11. In addition, at least one of the electrodes of the at least one semiconductor device is to be wired to the bond pads of the bonding parts 13. Moreover, the outer electrodes 15 each protrudes from one of the bonding parts 13. In practice, the boding parts 13 and the outer electrodes 15 are monolithically formed of a thin-walled metal material.

Additionally, the insulating material 17 is molded to substantially pack the base 11, and the bonding parts 13, so as to expose the top surface 115 and the bottom surface 117 of the base 11, and the bond pads. Furthermore, the insulating material 17 can also be molded to form a barricade surrounding the bond pads and the top surface 115 of the base 11. In practice, the insulating material 17 can be a polymer material or a ceramic material.

After the package of the at least one semiconductor device is finished, a heat generated during operation of the at least one semiconductor device is conducted from the top surface 115 to the bottom surface 117 of the base 11, and then it is dissipated from the bottom surface 117 of the base 11.

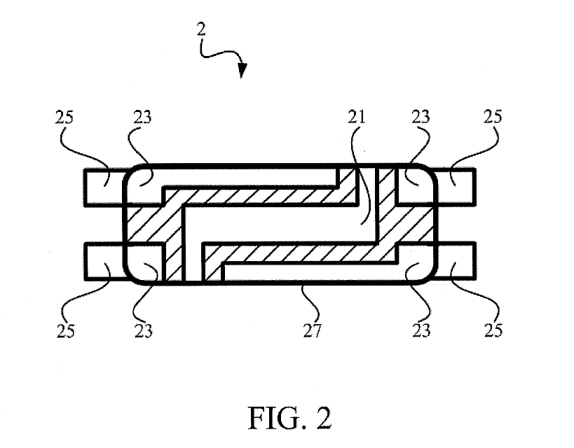

In another embodiment, as shown in FIG. 2, the substrate 2 for a package of a package of at least one semiconductor device (not shown) comprises a base 21, four bonding parts 23, four outer electrodes 25, and an insulating material 27.

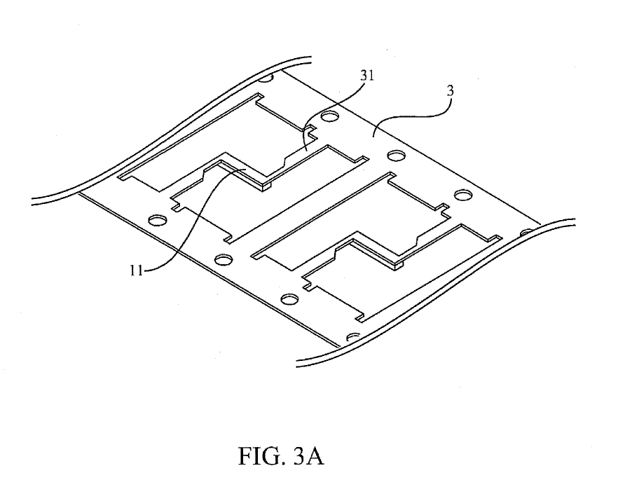

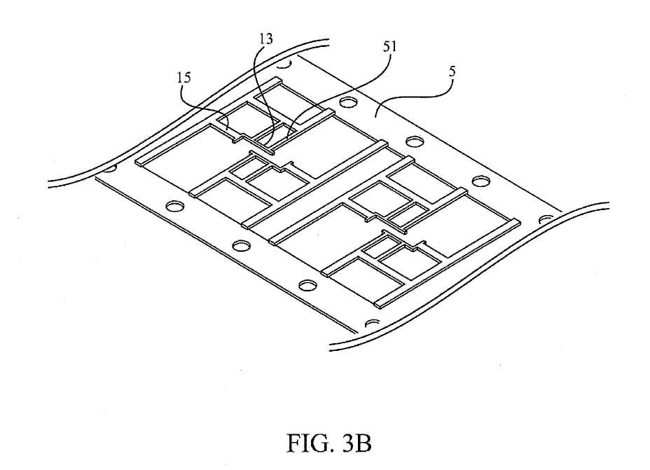

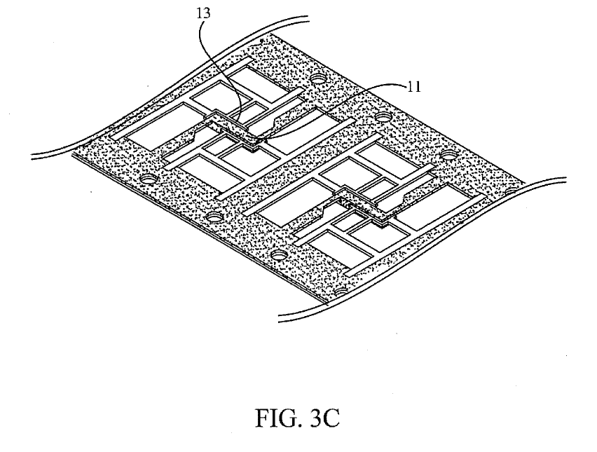

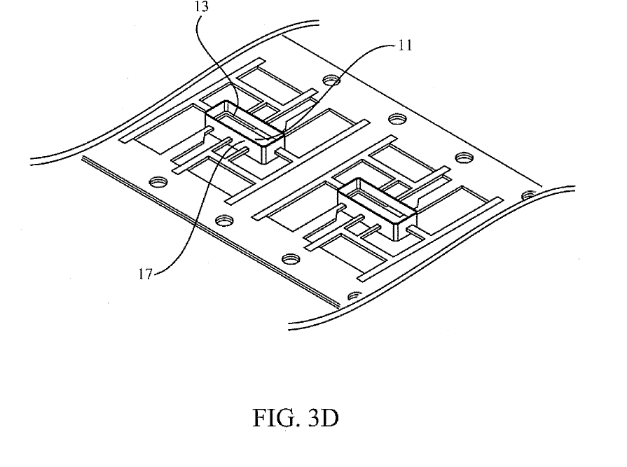

Please refer to FIG. 3A through 3D, which show a method of fabricating a substrate for a package of at least one semiconductor device according to one embodiment of the invention. The method of fabricating a substrate for a package of at least one semiconductor device, e.g. a semiconductor light-emitting device, in accordance with the present invention comprises 4 main steps.

First, as shown in FIG. 3A, a first metal plate is punched to form a first frame 3. Thus, a base 11 which has a bottom surface and a top surface is substantially formed at a center of the first frame 3. Furthermore, at least one first supporting part 31 is also formed, and each of them is to connect between the first frame 3 and the base 11. In practice, the first metal plate is a special-shaped metal plate or a normal-shaped metal plate. Moreover, in practice, the first metal plate can be a steel plate, a copper plate or an aluminum plate.

Afterward, referring to FIG. 3B, a second metal plate is punched to form a second frame 5 which can mate with the first frame 3. On the second frame 5, N bonding parts 13, which each has a respective bond pad, are formed apart from a center of the second frame 5. Moreover, N outer electrodes 15, which each is formed to connect between the second frame 5 and one of the bonding parts 13, are formed. Although N is equal to 2 in the embodiment, it should be noted that N is a positive integer larger than or equal to 2. In practice, the thickness of the second metal plate is smaller than or equal to that of the first metal plate.

In one embodiment, as shown in FIG. 3B, the second metal plate 5 is also punched to form at least one second supporting part 51 which each is formed to connect between the second frame 5 and one of the bonding parts 13. Furthermore, after the package of the at least one semiconductor device is finished, the at least one second supporting part 51 is also removed.

Referring to FIG. 3C, the third step is about aligning the second frame with the first frame, such that the bonding parts 13 are disposed around the circumference of the base 11 and spaced from the base 11.

The last step, as shown in FIG. 3D, is to mold an insulating material 17, e.g. a polymer material or a ceramic material, to substantially pack the base 11 and the bonding parts 13, so as to expose the top surface and the bottom surface of the base 11 and the bond pads. When the at least one semiconductor device is to be mounted on the top surface of the base 11, the electrodes of the at least one semiconductor device are to be wired to the first bond pads.

In one embodiment, the insulating material is also molded to form a barricade surrounding the bond pads and the top surface. Furthermore, a transparent polymer material can then be filled into the barricade to seal the at least one semiconductor device, the base, and the bond pads during the package of the at least one semiconductor device.

In one embodiment, the method of fabricating a substrate for a package of at least one semiconductor device can further comprise the step of selectively removing the first frame together with the at least one first supporting part and/or the second frame.

In one embodiment, after the package of the at least one semiconductor device is finished, a heat generated during operation of the at least one semiconductor device is conducted from the top surface to the bottom surface of the base, and then it is dissipated at the bottom surface of the base.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A substrate for a package of at least one semiconductor device, said substrate comprising:
a first metal plate, a first frame being formed on the first metal plate, at least one base being substantially formed at a center of the first frame, and at least one first supporting part being formed to connect between the first frame and the base, wherein the base has a circumference, a bottom surface and a top surface;
a second metal plate, a second frame being formed on the second metal plate, the second frame mating the first frame, N bonding parts being formed apart from a center of the second frame, each of the bonding parts having a respective bond pad, N outer electrodes being formed to connect between the second frame and one of the bonding parts, and N being a positive integer larger than or equal to 2, wherein the second frame is aligned with the first frame and the second frame is palletized on the first frame, such that the bonding parts are disposed around the circumference of the base and spaced from the base; and
an insulating material being molded to substantially pack the base and the bonding parts, so as to expose the top surface and the bottom surface of the base and the bond pads;
wherein the semiconductor device is to be mounted on the top surface of the base, and at least one electrode of the semiconductor device is to be wired to the bond pad.

2. The substrate of claim 1, wherein the first frame is formed by punching the first metal plate and the second frame is formed by punching the second metal plate.

3. The substrate of claim 1, wherein the first metal plate is made of a thick-walled metal material and the second metal plate is made of a thin-walled metal material.

4. The substrate of claim 1, wherein after the package of the semiconductor device is finished, a heat generated during operation of the semiconductor device is conducted from the top surface to the bottom surface of the base, and then is dissipated at the bottom surface of the base.

5. The substrate of claim 1, wherein the first metal plate is a special-shaped metal plate or a normal-shaped metal plate.

6. The substrate of claim 1, wherein the thickness of the first metal plate is larger than or equal to that of the second metal plate.

7. The substrate of claim 1, wherein the semiconductor device is a semiconductor light-emitting device.

8. The substrate of claim 1, wherein the insulating material is a polymer material or a ceramic material.

9. The substrate of claim 1, wherein the insulating material is also molded to form a barricade surrounding the bond pads and the top surface of the base, and a transparent polymer material is filled into the barricade to seal the semiconductor device, the base and the bond pads during the package of the semiconductor device.

10. The substrate of claim 1, wherein the second metal plate is punched to form at least one second supporting part which each is formed to connect between the second frame and one of the bonding parts.
